(19) United States
(12) Patent Application Publication
(10) Pub. No.: US 2021/0391245 A1
(43) Pub. Date: Dec. 16, 2021

(54) SEMICONDUCTOR PACKAGE DEVICE

(71) Applicant: NANYA TECHNOLOGY CORPORATION, New Taipei City (TW)

(72) Inventor: Wu-Der YANG, Taoyuan City (TW)

(21) Appl. No.: 16/899,566

(22) Filed: Jun. 11, 2020

(51) Int. Cl. H01L 23/498; H01L 23/31; H01L 25/16; H01L 49/02

(52) U.S. Cl. CPC H01L 23/49838; H01L 28/40; H01L 25/16; H01L 23/3128

(57) ABSTRACT

A semiconductor package device includes a substrate, a memory chip, and a decoupling array. The substrate has a top surface, a power end, and a grounding end. The memory chip is located on the top surface of the substrate and has a power pad in which the power pad is electrically connected to the power end at a node to receive electric power. A decoupling array is located on the top surface of the substrate, and the decoupling array has a plurality of decoupling capacitors connected in parallel. Each decoupling capacitor is electrically connected between the node and the grounding end.

### BACKGROUND

### Field of Disclosure

The present disclosure relates to a semiconductor package device. More particularly, the present disclosure relates to a semiconductor package device which can regulate input electric power.

### Description of Related Art

A significant recent trend in the development of technology related to semiconductor chips has been reductions in the sizes thereof. As a rapid increase in demand for small-sized semiconductor chips, their amounts of space for containing interior elements decrease.

In the semiconductor package field, a voltage regulator can't be applied to a semiconductor package device containing the aforementioned small-sized semiconductor chip due to its space. Therefore, the small-sized semiconductor chip consuming high energy is affected by outer electric power and the noise caused by itself.

As known from the above description, there is a need to develop a semiconductor package device which can reach miniaturization and solve the above problems about the outer electric power and the noise.

### SUMMARY

The invention provides a semiconductor package device includes a substrate, a memory chip, and a decoupling array. The substrate has a top surface, a power end, and a grounding end. The memory chip is located on the top surface of the substrate and has a power pad in which the power pad is electrically connected to the power end at a node to receive electric power. A decoupling array is located on the top surface of the substrate, and the decoupling array has a number of decoupling capacitors connected in parallel. Each decoupling capacitor is electrically connected between the node and the grounding end.

In some embodiments of the present disclosure, the memory chip has a grounding pad electrically connected to the grounding end of the substrate.

In some embodiments of the present disclosure, each decoupling capacitor has capacitance equal to or greater than 0.47 uF.

In some embodiments of the present disclosure, the semiconductor package device includes at least twenty-two decoupling capacitors.

In some embodiments of the present disclosure, the decoupling array has capacitance equal to or greater than 10 μF.

In some embodiments of the present disclosure, a first distance between the memory chip and any decoupling capacitor is shorter than a second distance between the decoupling capacitor and a corresponding edge of the substrate.

In some embodiments of the present disclosure, the decoupling capacitors have two sets of the decoupling capacitors, and the memory chip is located between the two sets of the decoupling capacitors.

In some embodiments of the present disclosure, each set of the decoupling capacitor has capacitance equal to or greater than 5 μF and at least eleven capacitors.

In some embodiments of the present disclosure, the two sets of the decoupling capacitors are respectively arranged in two straight rows, and the two straight rows are parallel.

In some embodiments of the present disclosure, the memory chip includes a number of metal pads respectively electrically connected to the decoupling capacitors, and the metal pads are located on a first surface of the memory chip.

In some embodiments of the present disclosure, the first surface of the memory chip is in contact with the top surface of the substrate, and the substrate has an opening exposing the metal pads.

In some embodiments of the present disclosure, the substrate has a conductive wire structure electrically connected to the decoupling capacitors, the power end, and the grounding end, such that each decoupling capacitor is electrically connected between the node and the grounding end.

In some embodiments of the present disclosure, the metal pads are electrically connected to the conductive wire structure through wire bonding.

In conclusion, the semiconductor package device in this disclosure has a decoupling array which includes a number of decoupling capacitors. The decoupling capacitors are electrically connected with each other to increase the capacitance of the decoupling array. In this way, input electric power can be shunted and a chip of the semiconductor package device can maintain its function. In another aspect, the semiconductor package device includes a face-down package structure. The decoupling capacitors are arranged in two straight parallel rows, and the memory chip is located between the two straight parallel rows of the decoupling capacitors. As a result, the needed space for containing the decoupling capacitors can decrease, and thus the semiconductor package device can miniaturize.

In some embodiments of the present disclosure, the semiconductor package device further includes a molding structure located on the top surface of the substrate, and the molding structure covers the memory chip and the decoupling capacitors.

It is to be understood that both the foregoing general description and the following detailed description are by examples, and are intended to provide further explanation of the disclosure as claimed.

### BRIEF DESCRIPTION OF THE DRAWINGS

The disclosure can be more fully understood by reading the following detailed description of the embodiment, with reference made to the accompanying drawings as follows:

FIG. 1 is a schematic diagram of a semiconductor package device in accordance with some embodiments of the present disclosure;

FIG. 2 is a top view of the semiconductor package device in FIG. 1;

FIG. 3 is a cross-section of the semiconductor package device taken along with a section line 3-3 in FIG. 2; and

FIG. 4 is a schematic circuit diagram of the semiconductor package device in FIG. 1 in accordance with some embodiments of the present disclosure.

### DETAILED DESCRIPTION

Reference will now be made in detail to the present embodiments of the disclosure, examples of which are illustrated in the accompanying drawings. Wherever possible, the same reference numbers are used in the drawings and the description to refer to the same or like parts.

The terms “over,” “to,” “between” and “on” as used herein may refer to a relative position of one layer with respect to other layers. One layer “over” or “on” another layer or bonded “to” another layer may be directly in contact with the other layer or may have one or more intervening layers. One layer “between” layers may be directly in contact with the layers or may have one or more intervening layers.

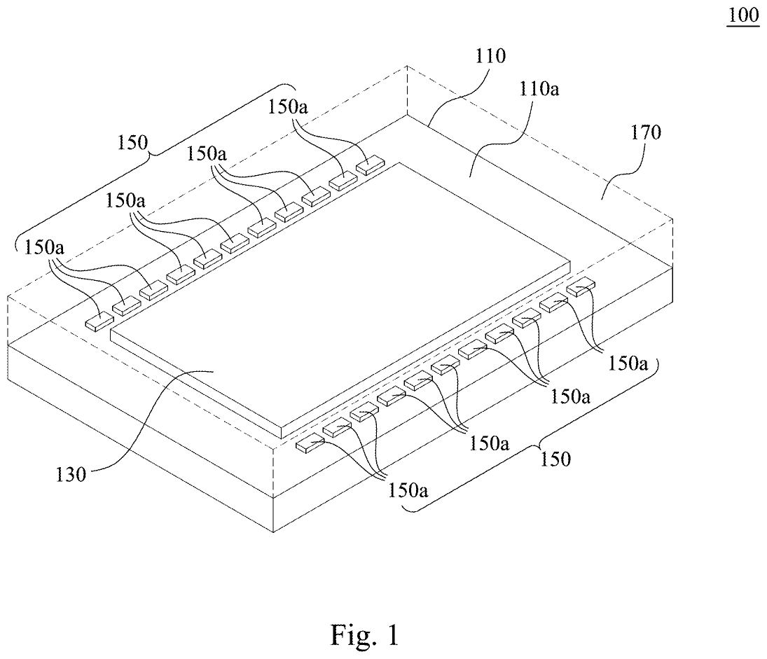

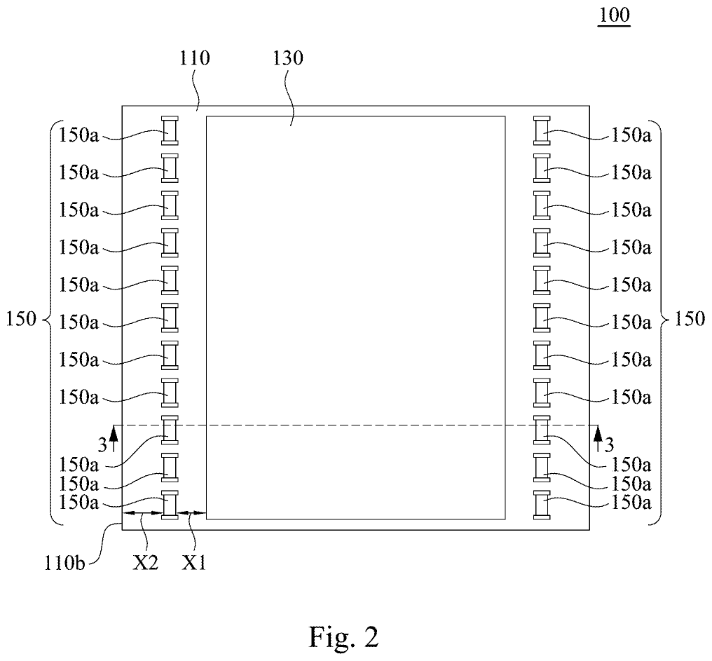

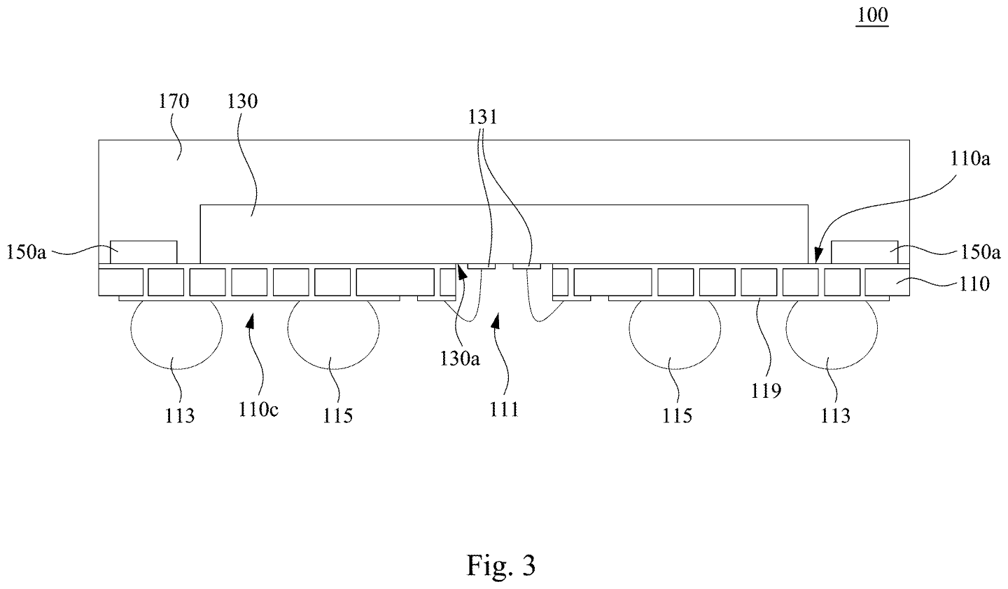

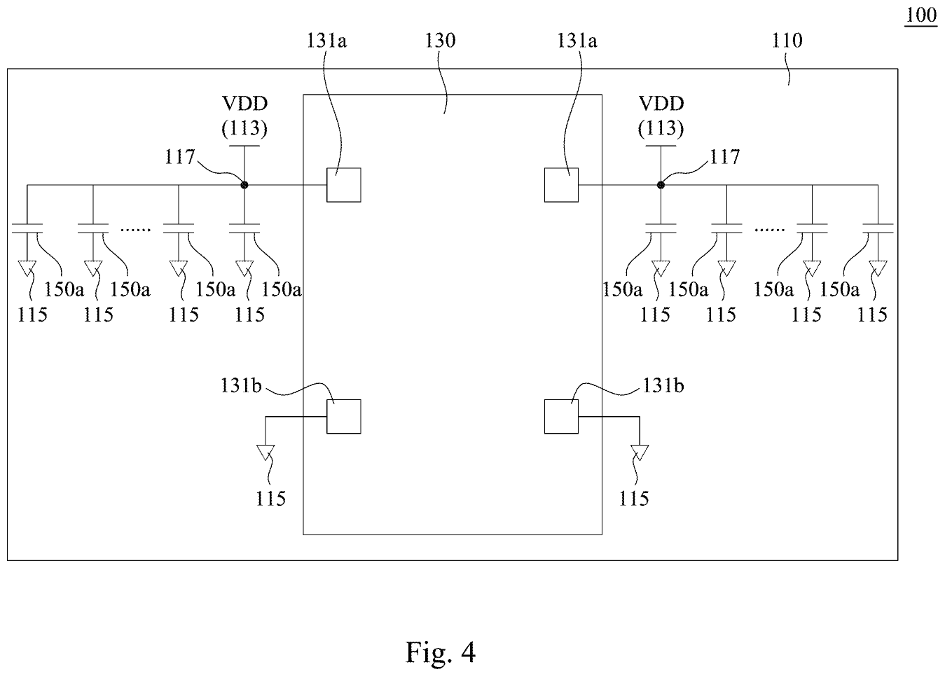

Reference is made from FIG. 1 through FIG. 4. FIG. 1 is a schematic diagram of a semiconductor package device 100. FIG. 2 is a top view of the semiconductor package device 100 in FIG. 1. FIG. 3 is a cross-section of the semiconductor package device 100 taken along with a section line 3-3 in FIG. 2. FIG. 4 is a schematic circuit diagram of the semiconductor package device 100 in FIG. 1. In an embodiment of the present disclosure, the semiconductor package device 100 includes a substrate 110, a memory chip 130, and a decoupling array 150. The substrate 110 has a top surface 110a, a power end 113, and a grounding end 115, in which the power end 113 can be electrically connected to an external power supply. The memory chip 130 is located on the top surface 110a of the substrate 110 and has a power pad 131a electrically connected to the power end 113 at a node 117 to receive electric power. A decoupling array 150 is located on the top surface 110a of the substrate 110, and the decoupling array 150 has a number of decoupling capacitors 150a connected in parallel. Each decoupling capacitor 150a is electrically connected between the node 117 and the grounding end 115. Furthermore, the memory chip 130 has a grounding pad 131b electrically connected to the grounding end 115 of the substrate 110.

The decoupling array 150 can shunt electric power from the power end 113, thereby preventing the transient currents thereof from damaging the memory chip 130. Moreover, the decoupling capacitors 150a are electrically connected in parallel with each other, and thus capacitance of the decoupling array 150 can increase as the number of the decoupling capacitors 150a grows. In this way, the decoupling array 150 can shunt higher electric power from the power end 113.

Specifically, the substrate 110 can be a copper clad laminate (CCL). The memory chip 130 can be a dynamic random access memory (DRAM) chip. The decoupling capacitors 150a of the decoupling array 150 can be a ceramic capacitor. The present disclosure is not limited in this respect.

The substrate 110 has a conductive wire structure 119 including copper wires. The conductive wire structure 119 is electrically connected to the decoupling capacitors 150a, the power end 113, and the grounding end 115, such that each decoupling capacitor 150a is electrically connected between the node 117 and the grounding end 115. The power end 113 and the grounding end 115 can be solder balls to receive and transmit electric power and signals. Such solder balls are located on a bottom surface 110c of the substrate 110, and thus the solder balls are electrically connected to the conductive wire structure 119. The present disclosure is not limited in this respect.

The semiconductor package device 100 further includes a molding structure 170. The molding structure 170 is shown in dotted lines in FIG. 1 but not shown in FIG. 2. The molding structure 170 is located on the top surface 110a of the substrate 110, and the molding structure 170 covers the memory chip 130 and the decoupling capacitors 150a. The molding structure 170 can include an epoxy molding compound to protect the memory chip 130 and the decoupling capacitors 150a from damaging. The present disclosure is not limited in this respect.

In embodiments of the present disclosure, the memory chip 130 further includes a number of metal pads 131 respectively electrically connected to the decoupling capacitors 150a. The metal pads 131, the power pad 131a, and the grounding pad 131b are located on a first surface 130a of the memory chip 130. The first surface 130a of the memory chip 130 is in contact with the top surface 110a of the substrate 110, and the substrate 110 has an opening 111 exposing the metal pads 131, the power pad 131a, and the grounding pad 131b. In this way, the semiconductor package device 100 is a face-down package structure, thereby reaching miniaturization. Moreover, the metal pads 131 are electrically connected to the conductive wire structure 119 through wire bonding. The present disclosure is not limited in this respect.

In embodiments of the present disclosure, the semiconductor package device 100 includes at least twenty-two decoupling capacitors 150a. Each decoupling capacitor 150a has capacitance equal to or greater than 0.47 uF. In this way, the decoupling array 150 has capacitance equal to or greater than 10 μF to shunt the electric power from the power end 113.

Specifically, the decoupling array 150 of the semiconductor package device 100 has two sets of the decoupling capacitors 150a, and the memory chip 130 is located between the two sets of the decoupling capacitors 150a. Each set of the decoupling capacitor 150a has capacitance equal to or greater than 5 μF. Since the two sets of the decoupling capacitors 150a are electrically connected in parallel, the decoupling array 150 has capacitance equal to or greater than 10 μF.

In addition, each set of the decoupling capacitor 150a includes at least eleven capacitors. The two sets of the decoupling capacitors 150a are respectively arranged in two straight rows, and the two straight rows are parallel. Through such configuration, the needed space to contain the decoupling capacitors can be reduced, thereby miniaturizing the semiconductor package device 100.

In embodiments of the present disclosure, a first distance X1 between the memory chip 130 and any decoupling capacitor 150a is shorter than a second distance X2 between the decoupling capacitor 150a and a corresponding edge 110b of the substrate 110. In this paragraph, the corresponding edge 110b refers to an edge of the substrate 110 which is abutting to the chosen decoupling capacitor 150a. Moreover, the first distance X1 is the shortest length between the memory chip 130 and any decoupling capacitor 150a. The second distance X2 is the shortest distance between the capacitor and the corresponding edge 110b of the substrate 110.

In conclusion, the semiconductor package device in this disclosure has a decoupling array which includes a number of decoupling capacitors. The decoupling capacitors are electrically connected with each other to increase the capacitance of the decoupling array. In this way, input electric power can be shunted and a chip of the semiconductor package device can maintain its function. In another aspect, the semiconductor package device includes a face-down package structure. The decoupling capacitors are arranged in two straight parallel rows, and the memory chip is located between the two straight parallel rows of the decoupling capacitors. As a result, the needed space for containing the decoupling capacitors can decrease, and thus the semiconductor package device can miniaturize.

Although the present disclosure has been described in considerable detail with reference to certain embodiments thereof, other embodiments are possible. Therefore, the spirit and scope of the appended claims should not be limited to the description of the embodiments contained herein.

It will be apparent to those skilled in the art that various modifications and variations can be made to the structure of the present disclosure without departing from the scope or spirit of the disclosure. In view of the foregoing, it is intended that the present disclosure cover modifications and variations of this disclosure provided they fall within the scope of the following claims.

1. A semiconductor package device, comprising:
a substrate having a top surface, a power end, and a grounding end;
a memory chip disposed on the top surface of the substrate having a power pad, wherein the power pad is electrically connected to the power end at a node to receive electric power; and
a decoupling array on the top surface of the substrate, wherein the decoupling array has a plurality of decoupling capacitors connected in parallel, and each decoupling capacitor is electrically connected between the node and the grounding end, wherein the memory chip includes a plurality of metal pads respectively electrically connected to the decoupling capacitors, and the metal pads are disposed on a first surface of the memory chip, wherein the first surface of the memory chip is in direct contact with the top surface of the substrate, and the substrate has an opening exposing the metal pads and at least a portion of the first surface of the memory chip, wherein the substrate has a conductive wire structure electrically connected to the decoupling capacitors, the power end, and the grounding end, such that each decoupling capacitor is electrically connected between the node and the grounding end, and the metal pads are electrically connected to the conductive wire structure through wire bonding.

2. The semiconductor package device of claim 1, wherein the memory chip has a grounding pad electrically connected to the grounding end of the substrate.

3. The semiconductor package device of claim 1, wherein each decoupling capacitor has capacitance equal to or greater than 0.47 uF.

4. The semiconductor package device of claim 1, wherein the decoupling capacitors include at least twenty-two decoupling capacitors.

5. The semiconductor package device of claim 1, wherein the decoupling array has capacitance equal to or greater than 10 μF.

6. The semiconductor package device of claim 1, wherein a first distance between the memory chip and any decoupling capacitor is shorter than a second distance between the decoupling capacitor and a corresponding edge of the substrate.

7. The semiconductor package device of claim 1, wherein the decoupling capacitors have two sets of the decoupling capacitors, and the memory chip is located between the two sets of the decoupling capacitors.

8. The semiconductor package device of claim 7, wherein the two sets of the decoupling capacitors are respectively arranged in two straight rows.

9. The semiconductor package device of claim 8, wherein the two straight rows are parallel.

10. The semiconductor package device of claim 7, wherein each set of the decoupling capacitor has capacitance equal to or greater than 5 μF.

11. The semiconductor package device of claim 7, wherein each set of the decoupling capacitors includes at least eleven capacitors.

12. (canceled)

13. (canceled)

14. (canceled)

15. (canceled)

16. The semiconductor package device of claim 1, further comprising a molding structure disposed on the top surface of the substrate, wherein the molding structure covers the memory chip and the decoupling capacitors.
